(19) United States
(12) Patent Application Publication
(10) Pub. No.: US 2012/0279651 A1
(43) Pub. Date: Nov. 8, 2012

(54) EPOXY COATING ON SUBSTRATE FOR DIE ATTACH

(76) Inventors: Wei Gu, Shanghai (CN); Zhong Lu, Shanghai (CN); Shrikar Bhagath, San Jose, CA (US); Chin-Tien Chiu, Taichung City (TW); Hem Takiar, Fremont, CA (US); XiangYang Liu, Shanghai (CN)

(21) Appl. No.: 13/257,285

(22) PCT Filed: May 5, 2011
(86) PCT No.: PCT/CN11/73688

§ 371 Date: Sep. 16, 2011

(51) Int. Cl. H01L 21/64; B05C 11/00; B32B 3/10; B05D 5/10; C09J 7/02; B05C 21/00; B05B 1/00

(52) U.S. Cl. 156/299; 118/504; 118/75; 118/301; 427/207.1; 428/195.1

(57) ABSTRACT

A system and method are disclosed for applying a die attach epoxy to substrates on a panel of substrates. The system includes a window clamp having one or more windows through which the epoxy may be applied onto the substrate panel. The size and shape of the one or more windows correspond to the size and shape of the area on the substrate to receive the die attach epoxy. Once the die attach epoxy is sprayed onto the substrate through the windows of the window clamp, the die may be affixed to the substrate and the epoxy cured in one or more curing steps. The system may further include a clean-up follower for cleaning epoxy off of the window clamp, and a window cleaning mechanism for cleaning epoxy off of the sidewalls of the windows of the window clamp.

### BACKGROUND OF THE INVENTION

1. Field

The present technology relates to fabrication of semiconductor devices.

2. Description of Related Art

The strong growth in demand for portable consumer electronics is driving the need for high-capacity storage devices. Non-volatile semiconductor memory devices, such as flash memory storage cards, are becoming widely used to meet the ever-growing demands on digital information storage and exchange. Their portability, versatility and rugged design, along with their high reliability and large capacity, have made such memory devices ideal for use in a wide variety of electronic devices, including for example digital cameras, digital music players, video game consoles, PDAs and cellular telephones.

A semiconductor memory device typically consists of a substrate, such as a printed circuit board, which is etched to include a conductance pattern having contact pads and electrical traces. A large number of semiconductor die are formed together on a semiconductor wafer, and then diced into individual semiconductor die. One or more semiconductor die are then bonded to the substrate and electrical connections are made between die bond pads on the one or more semiconductor die and the contact pads of the substrate. The signals may then be transferred between the one or more semiconductor die and an external host device via the conductance pattern.

Die attach films (DAF) are typically used to bond the semiconductor die to the substrate. Typically, DAF is attached to the back (inactive) side of an entire semiconductor wafer prior to dicing of the individual semiconductor die. A dicing tape is then applied over the DAF to hold the respective die together after dicing. After the DAF and dicing tape are applied, the wafer may be cut, for example with a dicing saw. During the cutting process, issues such as a DAF burring, or anchor effect, may occur. An anchor effect is a phenomenon where the DAF bites into the dicing tape where the DAF is cut by the blade. The DAF anchor effect can increase the load required to pick up the die after dicing and that may lead to die breakage or defective pick-up.

### DESCRIPTION OF THE DRAWINGS

FIG. 1 is a flowchart for forming a semiconductor die according to embodiments of the present system.

FIG. 2 is a top view of a semiconductor wafer from which a plurality of semiconductor die according to embodiments of the present system may be fabricated.

FIG. 3 is an enlarged top view of a semiconductor die from the wafer of FIG. 2.

FIG. 4 is a flowchart for fabrication of a substrate for use with the present system, and assembly of a semiconductor device using the substrate and semiconductor die.

FIG. 5 is a flowchart showing further detail of the die attach epoxy step of FIG. 4.

FIG. 6 is a top view of a substrate panel according to the present technology.

FIG. 7 is an enlarged top view of a substrate from the substrate panel of FIG. 6.

FIG. 8 is a top view of a window clamp according to embodiments of the present system.

FIG. 9 is a top view of a spray head and window clamp positioned over a substrate panel according to the present technology.

FIG. 10 is a perspective view of a spray head and window clamp positioned over a substrate panel according to the present technology.

FIG. 11 is an edge view of a spray head and window clamp positioned over a substrate panel according to the present technology.

FIG. 12 is a perspective view of a spray head, window clamp and clean-up follower positioned over a substrate panel according to the present technology.

FIG. 13 is an edge view of a window-cleaning mechanism positioned to clean sidewalls of a window of a window clamp.

FIG. 14 is an edge view of a window-cleaning mechanism cleaning the sidewalls of a window of a window clamp.

FIG. 15 is an edge view of a semiconductor package according to the present technology.

FIG. 16 is a window clamp according to an alternative embodiment of the present technology.

FIGS. 17-22 are different configurations of a window in a window clamp per the present technology.

### DETAILED DESCRIPTION

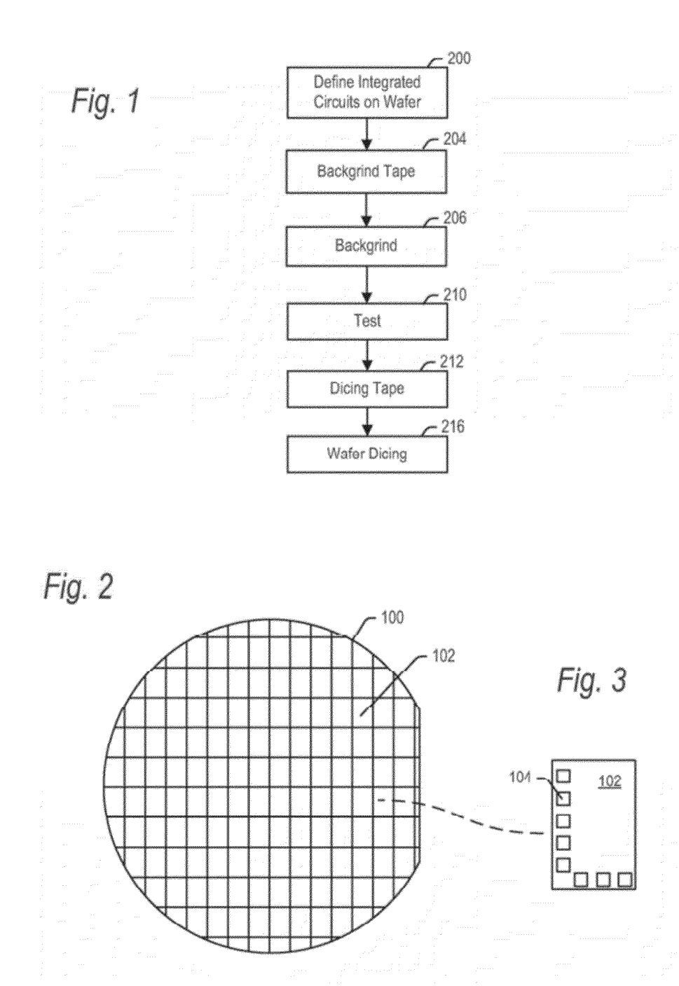

Embodiments will now be described with reference to FIGS. 1 through 22, which relate to a semiconductor device including a semiconductor die bonded to a substrate via an epoxy layer applied to a panel of substrates. It is understood that the present invention may be embodied in many different forms and should not be construed as being limited to the embodiments set forth herein. Rather, these embodiments are provided so that this disclosure will be thorough and complete and will fully convey the invention to those skilled in the art. Indeed, the invention is intended to cover alternatives, modifications and equivalents of these embodiments, which are included within the scope and spirit of the invention as defined by the appended claims. Furthermore, in the following detailed description of the present invention, numerous specific details are set forth in order to provide a thorough understanding of the present invention. However, it will be clear to those of ordinary skill in the art that the present invention may be practiced without such specific details.

The terms “top,” “bottom,” “upper,” “lower,” “vertical” and/or “horizontal” are used herein for convenience and illustrative purposes only, and are not meant to limit the description of the invention inasmuch as the referenced item can be exchanged in position.

A process for forming semiconductor die for use with the present system will now be described with reference to the flowchart of FIG. 1, and the top views of FIGS. 2 and 3. FIG. 2 shows a top view of a semiconductor wafer 100 for batch processing a plurality of semiconductor die 102 (one of which is labeled in FIG. 2). FIG. 3 shows a single semiconductor die 102 diced from wafer 100 as explained below. The integrated circuit components of semiconductor die 102 may be formed on wafer 100 in step 200 by known processes such as film deposition, photolithography, patterning, and diffusion of impurities. In embodiments, the die 102 may be memory die such as NAND flash memory die. However, die 102 may be other types of semiconductor die in further embodiments, such as for example NOR, DRAM and various other memory die.

The formation of the integrated circuit may include the formation of die bond pads 104 (one of which is labeled in FIG. 3) by known processes including but not limited to plating, evaporation, screen printing, or various deposition processes. Bond pads 104 are used to electrically couple the semiconductor die 102 to another semiconductor die, or to a printed circuit board, leadframe or other substrate as explained hereinafter. The bond pads 104 shown in FIG. 3 are for illustrative purposes only and there may be more or less bond pads along an edge of die 102 than are shown in FIG. 3. Moreover, while the bond pads 104 are shown along two edges, the bond pads 104 may be provided along one, three or four edges in further embodiments.

In step 204, the top (active) surface of the wafer 100 including the integrated circuits is taped for a backgrind process. In step 206, the taped surface may be supported on a chuck and the backgrind process may be performed on the back (inactive) surface of wafer 100 as is known in the art to thin the die 102 to the desired thickness. In step 210, the die 102 on wafer 100 may be tested for functional defects. Such tests include for example wafer final test, electronic die sort and circuit probe.

In step 212, the wafer may be transferred from the backgrind chuck, and a dicing tape may be applied to the inactive surface of the wafer 100. In step 216, the back surface of the die may be supported on a chuck, and each of the die 102 may be diced from the wafer. The dicing process may involve a first set of vertical cuts (from the perspective of FIGS. 2 and 3) along boundaries between adjacent die 102, and a second set of horizontal cuts (again from the perspective of FIGS. 2 and 3) along boundaries between adjacent die 102. The horizontal cuts may be done prior to the vertical cuts in alternative embodiments. The dicing step may be performed by a dicing blade or by laser. Upon completion of the dicing step, the die may be picked and placed onto a substrate, as explained below. As there is no DAF tape applied to the wafer 100, the difficulties associated with DAF burring may be avoided.

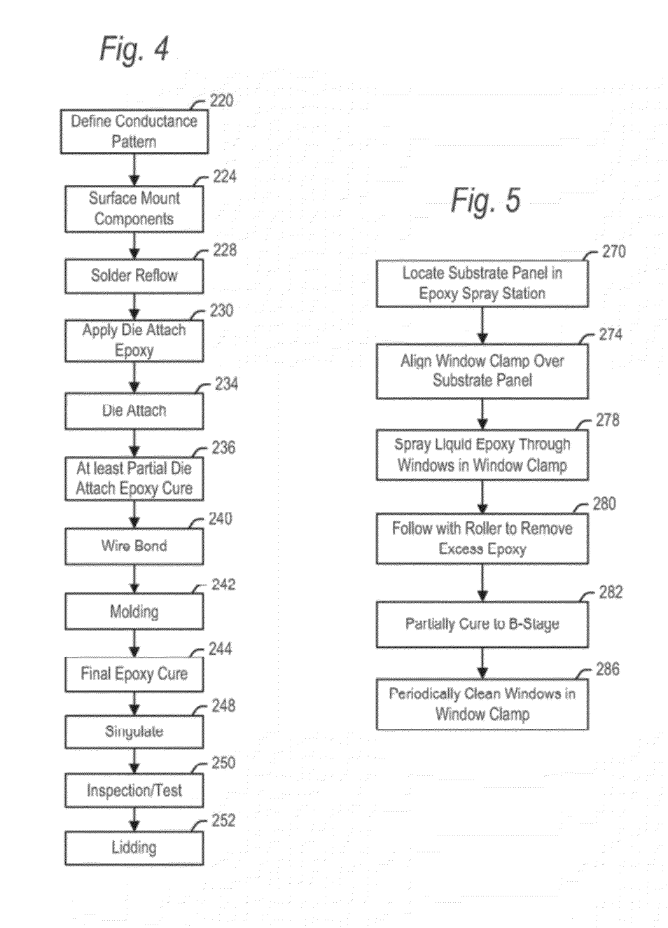

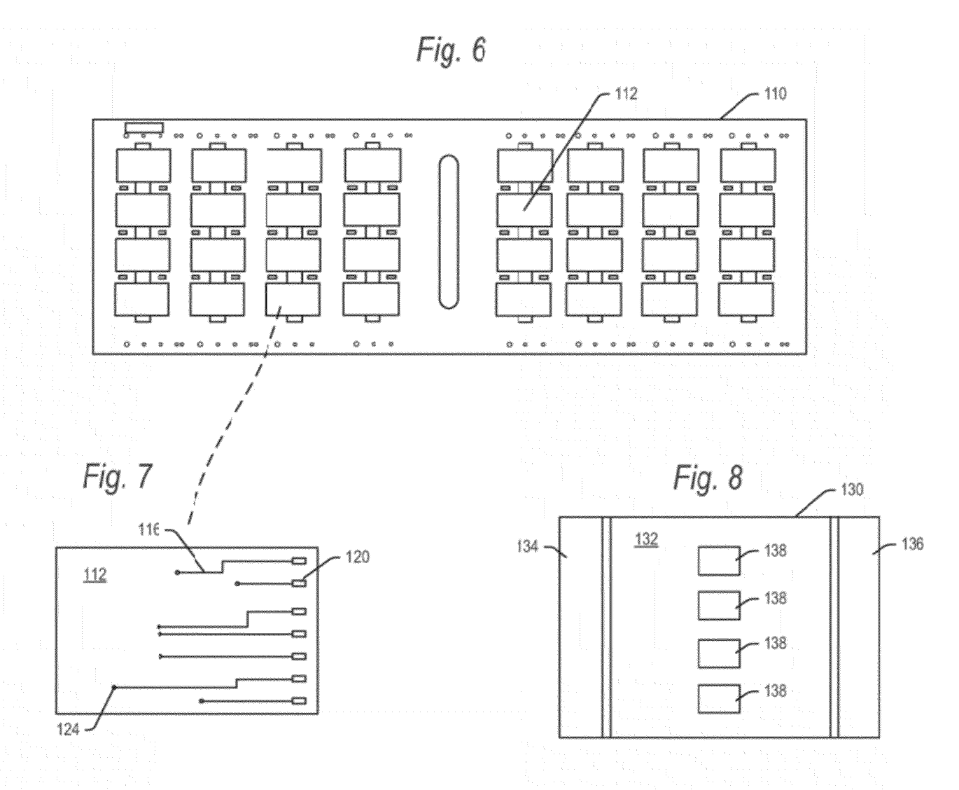

The flowchart of FIGS. 4 and 5 show the steps for forming a substrate panel in accordance with the present system, and for mounting semiconductor die 102 on the substrate panel. FIG. 6 shows a top view of a substrate panel 110 including a plurality of substrates 112 (one of which is numbered in FIG. 6). In the example shown and described below, the substrates 112 may for example be printed circuit boards (PCB), but the substrates may be leadframes or tape automated bonding (TAB) tapes in further embodiments. The following describes the formation of a single substrate 112. It is understood that the following description takes place for each substrate on the panel 110.

Each substrate 112 may be formed of a core having top and/or bottom conductive layers. The core may be formed of various dielectric materials such as for example, polyimide laminates, epoxy resins including FR4 and FR5, bismaleimide triazine (BT), and the like. Although not critical to the present invention, the core may have a thickness of between 40 microns (μm) to 200 μm, although the thickness of the core may vary outside of that range in alternative embodiments. The core may be ceramic or organic in alternative embodiments.

The conductive layer(s) surrounding the core may be formed of copper or copper alloys, plated copper or plated copper alloys, copper plated steel, or other metals and materials known for use on substrate panels. The conductive layers may have a thickness of about 10 μm to 25 μm, although the thickness of the layers may vary outside of that range in alternative embodiments.

In step 220, one or both of the conductive layers on the core may be etched into a conductance pattern as is known for communicating signals between the semiconductor die 102 and an external device (not shown). The etched conductance pattern may include electrical traces 116 and contact pads 120 on an upper surface of the substrate 112. As is known, vias 124 may also be provided for communicating signals to different layers of the substrate 112. Where the semiconductor device is a land grid array (LGA) package, contact fingers (not shown) may also be defined on a lower surface of the substrate 112. As is known in the art, a layer of solder mask may be applied to the top or bottom surfaces of substrate 112, and the contact pads 116 and/or contact fingers may be plated with one or more gold layers, for example in an electroplating process.

In step 224, surface mounted components may be soldered to the contact pads 120 of the substrate 112. The surface mounted components may include passive devices such as resistors, capacitors and/or inductors. The solder may be reflowed in a known reflow process in step 228.

In step 230, a layer of die attach epoxy may be sprayed onto each substrate 112 on panel 110. Further details of step 230 are explained with reference to the flowchart of FIG. 5 and the different views of FIGS. 8 through 22. In step 270, the substrate panel 110 is positioned on a table in an epoxy spray station. In step 274, a window clamp 130 is positioned over the substrate panel. An example of a window clamp 130 is shown in FIGS. 8 through 11. The window clamp may be formed of metal, such as for example stainless steel (grade 440 C), though other rigid materials may be used. The window clamp 130 may include a window section 132 having flanges 134 and 136 (FIGS. 8 and 11) on either side. The window section 132 may include a plurality of windows 138, which are openings formed in and completely through the clamp 130.

In embodiments, there may be a single column of windows 138 in window section 132, and the number of windows 138 may match the number of substrates 112 in a column on the panel 110. In the embodiment shown, there are four substrates 112 in a column on panel 110, and there are four windows 138 on the window clamp 130. It is understood that there may be greater or fewer substrates 112 in a column on panel 110, and a corresponding greater or fewer windows 138 on window clamp 130. It is further understood that there may be a larger or smaller number of substrates 112 in a column on panel 110 than there are in a column of windows 138 on clamp 130. Moreover, as explained below, there may be multiple columns of windows 138 on clamp 130 to match the number of columns, or a portion of the number of columns, of substrates 112 on panel 110.

In embodiments, each of the windows 138 may be the same size and shape as the semiconductor die 102 to be mounted on the substrate 112 as explained below. The windows 138 may correspond in length and width to any length and width of die 102 that may be used. The windows are also oriented in the same orientation that die 102 are to be mounted on the substrate 112. Each window 138 is similarly spaced from each other a distance corresponding to the positions of the semiconductor die 102 that get mounted to a column of substrates 112.

In embodiments, each window 138 is defined by sidewalls that are perpendicular to the major planar surfaces of window section 132. The thickness of the window section 132 at the windows 138 may for example be 0.4 mm. It is understood that the angle of the sidewalls between the major planar surface of the window section 132 may be less than or greater than 90° in further embodiments. In such embodiments, the size of the window 138 may correspond to the size of the die 102 at the top surface of window section 132 or at the bottom surface of window section 132.

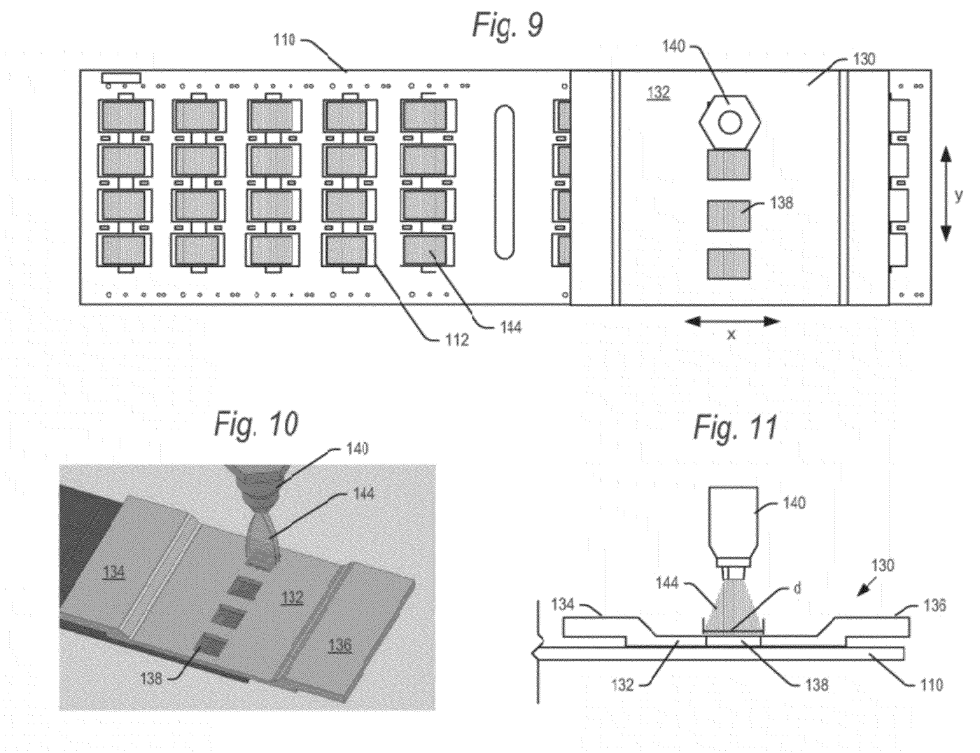

In step 274, the window clamp 130 is aligned over the substrate panel 110. For example, at the start of the epoxy spray process, the window clamp 130 may be aligned over the first (leftmost) column of substrates 112 on panel 110 shown in FIG. 9. Liquid epoxy is then sprayed through the windows 138 onto the substrate in step 278. The window clamp 130 masks the substrate panel so that the epoxy is sprayed onto a column of substrates 112 only over the areas on the respective substrates that are to receive a semiconductor die 102. Once epoxy has been applied to a column of substrates through windows 138, the window clamp 130 may then be moved with respect to the substrate panel so that it is positioned over the next column of substrates, and the liquid epoxy is then sprayed onto the next substrate column. It is understood that the spray process need not start over the leftmost column of substrates 112 on panel 110, and may proceed in any order in applying the liquid epoxy to the columns of substrates 112.

In embodiments, the substrate panel 110 may be held stationary while the window clamp 130 moves, or the substrate panel 110 may move, while the window clamp 130 is held stationary. This process may be repeated until liquid epoxy is applied to each substrate 112 on the panel 110.

The window clamp 130 may be aligned at the desired positions over the substrate panel 110 by a variety of alignment schemes, including optically. In an optical alignment embodiment, an emitter and receiver may be used to find fiducial holes and/or reference markers in the substrate panel 110 and on the window clamp 130 to indicate when the panel and clamp are aligned. Additionally or alternatively, a camera or other imaging device may be used which images the substrate panel 110 and/or window clamp 130 as it moves to facilitate alignment of the panel and clamp.

In embodiments, the window clamp 130 may be supported by a pair of holders (not shown) that engage the flanges 134, 136. As seen for example in FIG. 11, the flanges 134, 136 are vertically offset from the window section 132. Thus, the holders are able to grasp the flanges 134, 136 above and below the flanges to secure the window clamp 130 to the holders. In further embodiments, the holders may simply engage beneath the flanges 134, 136 with the window clamp 130 then being supported on the holders by gravity. The holders may be supported for translation to move the window clamp 130 along the x-direction (FIG. 9) relative to the substrate panel 110. In further embodiments, the holders may be for translation in both the x- and y-directions.

The vertical offset of the flanges 134, 136 from the window section 132 allows the window clamp 130 to be supported and/or translated while the window section 132 lies flat against the substrate panel 110. In embodiments, the window section 132 may lie flush against the substrate panel 110 during the epoxy spaying process or the window section 132 may be slightly spaced from the substrate panel 110.

FIGS. 10 and 11 show a spray head 140 for applying an epoxy 144 onto window clamp 130 and through windows 138. The spray head may be a known fluid-dispensing mechanism for applying liquid epoxy, such as for example that provided by Nordson Asymtek, Carlsbad, Calif., USA. Spray heads from other manufactures may be used. The type of epoxy which may be used is Ablestik WBC8901-UV die attach epoxy from Henkel AG & Co. KGaA, having headquarters in Düsseldorf, Germany. Other types of epoxy may be used.

The epoxy 144 may be applied as an A-stage liquid from spray head 140. As explained below, the epoxy may subsequently undergo UV and/or thermal heating to cure the epoxy to one or more intermediate B-stages, and then ultimately to a fully-cured C-stage. When applied as an A-stage liquid, the epoxy 144 may have a viscosity from 1,000 to 10,000 cP at 5 rpm, with the spray head 140 maintained at a temperature of 60° C. It is understood that these parameters are by way of example only, and each may vary in further embodiments. The epoxy may be sprayed onto the substrate 112 through window 138 to a thickness of approximately between 5 μm to 50 μm, though the thickness may vary above or below this range in further embodiments.

As indicated in FIGS. 9 and 10, the spray head 140 may traverse in the y-direction to apply the epoxy 144 through each window 138, one window at a time. The spray head 140 may traverse up or down the column. The diameter, d (FIG. 11), of sprayed epoxy at the surface of the window section 132 is at least as great as the corresponding dimension of the windows 138 (the dimension transverse to the direction of travel of the spray head 144) to ensure that epoxy is sprayed across the entire area of each window 138. In the embodiment shown, the epoxy spray 144 is applied one window at a time as the spray head traverses in the y-direction down a column. However, it is contemplated that epoxy 144 may be applied to more than one window 138 simultaneously.

The embodiments described above relate to window clamp having windows arranged in a column to match a column of substrates on the substrate panel. In an alternative embodiment, the window clamp may have windows arranged in a row to match a row of substrates on the substrate panel.

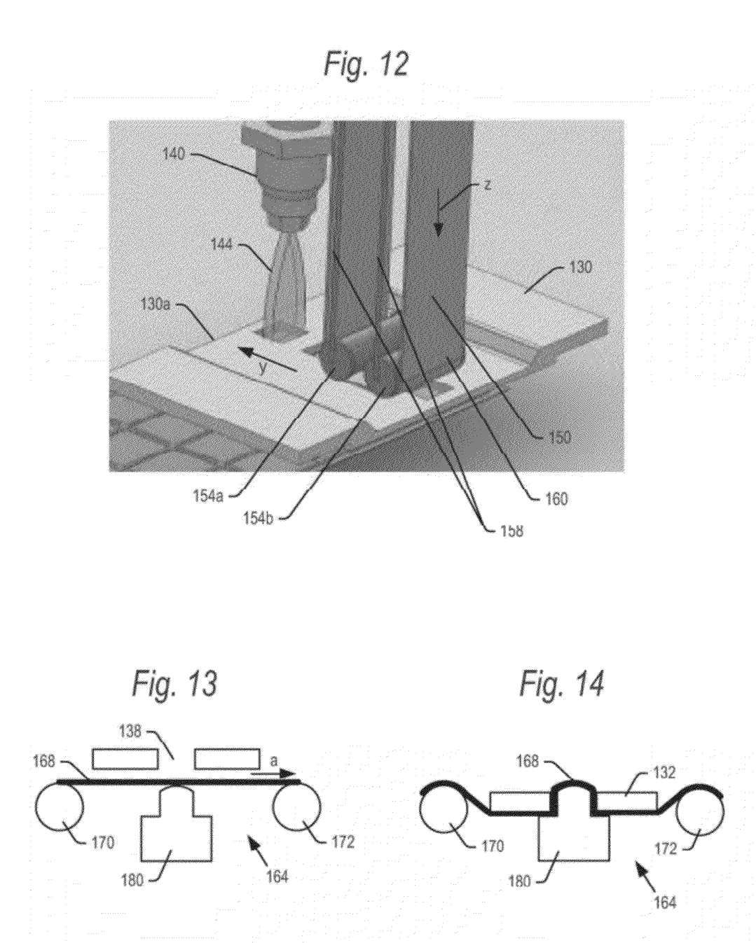

As the spray head traverses the column of windows 138 in window section 132, the sprayed epoxy may accumulate on the window section 132 in the spaces between and around the windows 138. Over time, this buildup of epoxy may affect application of the epoxy through the windows 138. Therefore, in one embodiment, the present system may remove the epoxy 144 which is sprayed onto the window section 132 in a step 280. One mechanism for removing the epoxy 144 is shown in FIG. 12 and described below.

FIG. 12 illustrates the window clamp 130 and spray head 140 spraying epoxy 144 onto the clamp 130. FIG. 12 further shows a clean-up follower 150 for removing epoxy 144 that is sprayed onto the clamp around windows 138. Clean-up follower 150 includes a pair of rollers 154a, 154b supported for rotation on two pairs of shafts 158 (only one shaft 158 from each pair is visible in FIG. 12; the second shaft from each pair may support the rollers 154a, 154b on their opposite end). The top end of clean up follower 150 (not shown) may have a base for supporting the two pairs of shafts 158, and a towel feed which includes a drive motor for feeding a towel 160 around rollers 154a, 154b. For example, the drive motor may drive the towel 160 in the z-direction around the rear roller 154b, and then in the opposite direction past front roller 154a. The towel feed at the top of clean-up follower 150 may itself include a pair of rollers, a supply roller for supplying a clean section of towel 160 down to roller 154b, and a take-up roller for receiving a used section (including removed epoxy) of towel 160 from roller 154a.

The base of clean-up follower 150 may be supported to translate, or follow, the spray head 140 as it traverses the column of windows 138. The clean-up follower 150 may for example be mounted to the same translation mechanism advancing the spray head along the y-direction, or the clean-up follower 150 may be mounted on a separate translation mechanism from the spray head 140. The spray head 140 may spray epoxy to the edge 130a of the window clamp 130, whereupon it stops spraying, but it may continue to translate in the y-direction to allow the clean-up follower 150 to reach and clean to the edge 130a of the window clamp 130.

In embodiments, the towel 160 may be an absorbent fiber cloth. The support shafts 158 position the rollers 154a, 154b adjacent the surface of the window section 132, so that the towel 160 contacts the surface of the window section 132 as it translates to absorb and remove epoxy that has been sprayed onto the window section 132.

It is understood that clean-up follower 150 may have a wide variety of other configurations for driving a towel across the surface of window section 132 to remove epoxy that has been sprayed onto the window section 132. In one alternative, the clean-up follower may include a single roller 154. Other mechanisms are contemplated. Moreover, in a further embodiment, the clean-up follower 150 may be omitted altogether. In such embodiments, the window clamp 130 may be changed periodically to prevent excessive buildup of epoxy on the surface of the clamp 130.

FIG. 9 shows the window clamp 130 and spray head 140 having applied epoxy 144 to about two-thirds of the substrates 112 (the clean-up follower 150 is omitted for clarity). Once the A-stage liquid epoxy 144 has been applied to all of the substrates 112 on panel 110, the panel 110 may be moved to a partial curing station in step 282 to partially cure the epoxy 144 to a B-stage. This partial curing step prevents bleeding of the epoxy, but still allows the epoxy to receive and bond a semiconductor die to the substrate as explained below. The curing step 282 may be a UV curing step, but may be a thermal curing step in further embodiments.

While the clean-up follower 150 can remove epoxy from a top surface of window clamp 130, epoxy may also accumulate on the sidewalls of windows 138. Therefore, in embodiments, a window cleaning step 286 may periodically be performed. FIGS. 13 and 14 illustrate an example of a window-cleaning mechanism 164 including a towel 168 connected between a supply roller 170 and a take-up roller 172. Take-up roller 172 may be driven by a motor (not shown) to move towel 168 between rollers 170, 172 in the direction of arrow a.

Window-cleaning mechanism 164 may clean windows 138 of window clamp 130 when the window clamp 130 is separated from a substrate panel 110 (either in the same tool where the epoxy 144 is sprayed or in a separate tool). The window-cleaning mechanism 164 further includes a plunger 180, which is formed of a size and shape approximating that of a window 138. The plunger 180 may be slightly smaller than a window 138 to leave space for the towel between the sidewalls of a window 138 and plunger 180.

In operation, the window clamp 130 may be supported over the window cleaning mechanism 164, with a window 138 aligned over the plunger 180. The plunger may then be driven upward, through the aligned window 138, so that the towel 168 is forced up through the window. The towel 168 contacts the sidewalls of the window to absorb and remove epoxy which may have deposited on the sidewalls. The plunger may then be removed, the window clamp 130 is moved to align with the next window 138 to be cleaned over the plunger 180, and the process is repeated in succession until each window 138 is cleaned. This operation may be performed periodically, for example after epoxy 144 is applied to an entire panel 110. It may also be performed after epoxy is applied to one or more columns of substrates on panel 110. It may be performed at other intervals in further embodiments. Moreover, in a further embodiment, the window-cleaning mechanism 164 may be omitted altogether. In such embodiments, the window clamp 130 may be changed periodically to prevent excessive buildup of epoxy within the sidewalls of windows 138.

Returning now to the flowchart of FIG. 4, after the die attach epoxy is applied as detailed above, a die 102 may be attached to each substrate 112 on top of the B-stage epoxy 144 in step 234. In step 236, a further curing of the die attach epoxy 144 is performed. In embodiments, this may be an intermediate cure sufficient to bond the semiconductor die 102 in position, but not yet at C-stage. In further embodiments, the further curing step 236 may be a complete curing of the epoxy 144 to its final C-stage. Where the epoxy is partially cured short of the C-stage, the curing step 236 may be performed in a thermal heating process at a temperature of ______ for a period of ______. It is understood that this temperature and duration may vary in further embodiments. Where the epoxy is fully cured to the C-stage, the curing step 236 may be performed in a thermal heating process at a temperature of ______ for a period of ______. It is understood that this temperature and duration may vary in further embodiments.

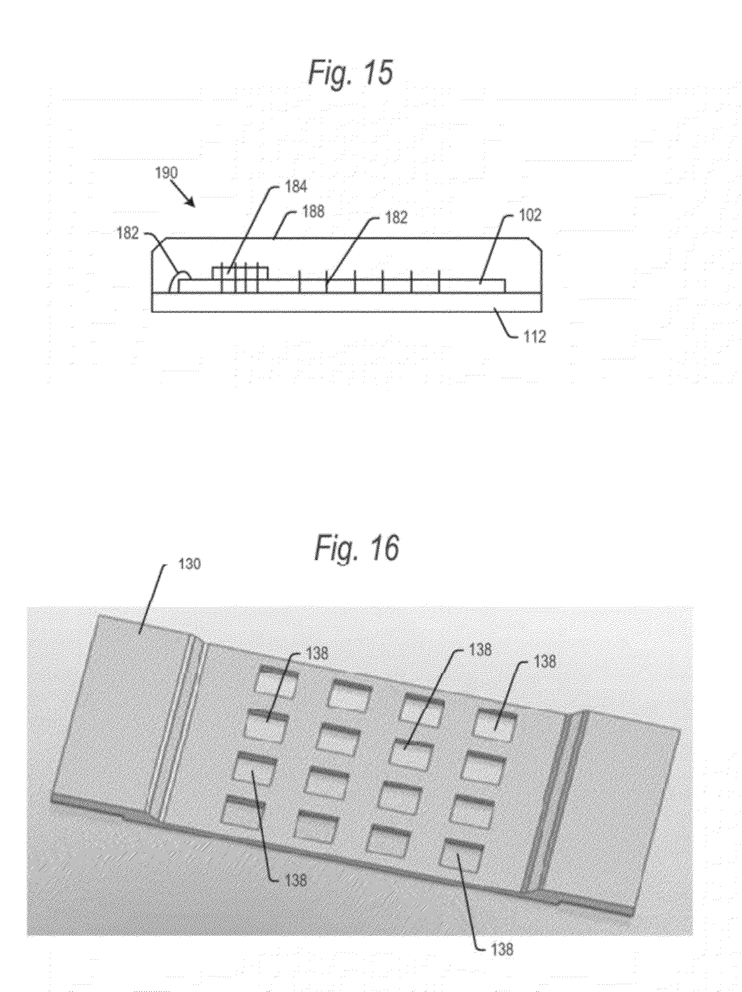

In step 240, the die 102 may be wire bonded to the substrate 112, by connecting a conductive wire between die bond pads 104 on die 102 and contact pads 120 on substrate 112. It is contemplated that one or more additional die may be mounted on top of die 102. If additional die are mounted, these die may also be wire bonded to the substrate in step 240. FIG. 15 shows an edge view of a die 102 wire bonded to substrate 112 via wire bonds 182. A controller die 184 may also be mounted on top of the die stack and wire bonded to the substrate in step 240. The controller die 184 may for example be an ASIC, but may be other controller die in further embodiments.

In step 242, after the die 102 and any additional die on the stack are wire bonded to the substrate 112, the die stack may be encased within the molding compound 188 in step 242. Molding compound 188 may be a known epoxy resin such as for example available from Sumitomo Corp. and Nitto Denko Corp., both having headquarters in Japan.

As noted above in step 236, after the die 102 are mounted on the substrate 112, the epoxy 144 may be only partially cured. If so, after the encapsulation step 242, a final curing step 244 may be performed to complete curing of the epoxy 144 to a C-stage epoxy, where it is set. If the complete C-stage epoxy cure was performed earlier in step 236, step 244 may be omitted.

The encapsulated and cured devices may then be singulated from the substrate panel in step 248 to form finished semiconductor devices 190 seen in FIG. 15. The finished devices 190 may be inspected and tested in step 250. In some embodiments, the finished semiconductor device 190 may optionally be enclosed within a lid in step 252.

The window clamp 130 described above may include a single column of windows 138. As noted, there may alternatively be more than one column of windows 138. Such an embodiment is shown in FIG. 16. In the embodiment of FIG. 16, the window clamp 130 has an array of four columns of windows 138. If used with the substrate panel 110 shown in FIG. 6, the panel may be placed over the first set of sixteen substrates on the left (or vice-versa), and all sixteen may be coated with epoxy while the clamp 130 remains stationary. The clamp 130 may then be moved over to the second set of sixteen substrates on the right (or vice-versa), and the second set may be coated. It is contemplated that the window clamp 130 may have as many columns as there are columns of substrates on panel 110. In these embodiments, the windows in each column align with the positions where the epoxy is to be applied to each substrate.

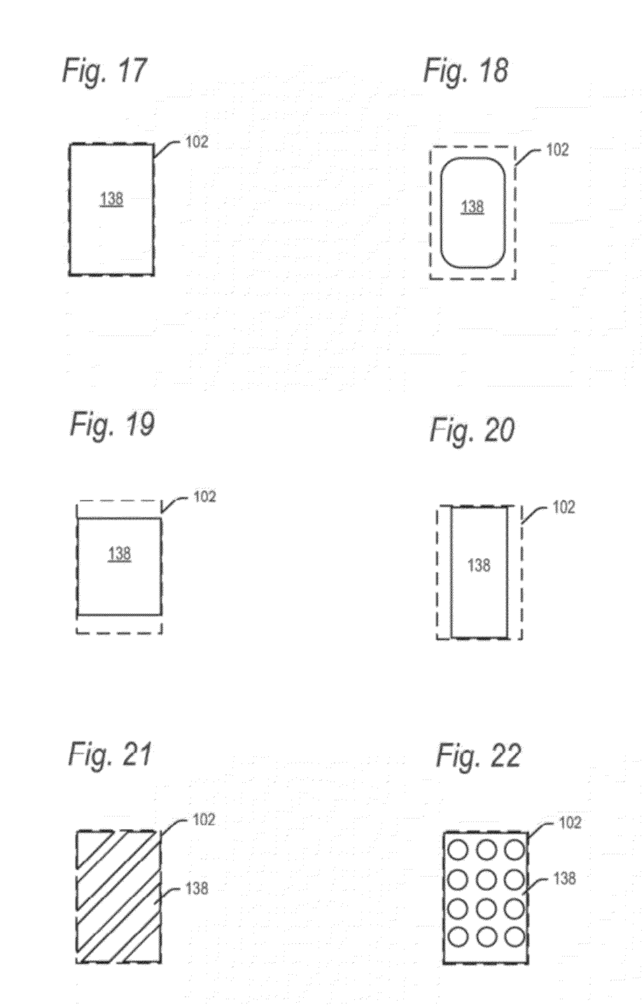

FIGS. 17-22 illustrate different embodiments of windows 138 which may be provided on window clamp 130. FIG. 17 shows the above-described embodiment, where the window 138 matches the general size, shape and orientation of the semiconductor die 102 to be mounted on the epoxy 144 applied through the window 138. (The semiconductor die 102 is shown in dashed in each of FIGS. 17-22 for clarity). In FIG. 18, the window 138 is smaller in length and width than the die 102, resulting in a smaller epoxy area than die area. The shape of the window 138 need not be rectangular. In embodiments, the window 138 may be round, oval or elliptical. In the embodiment of FIG. 18, the corners are shown rounded.

In FIG. 19, the window 138 has a shorter length than the die 102, and in FIG. 20, the window 138 has a shorter width than the die 102.

Up to this point, window 138 has been described as being a unitary opening. It need not be in further embodiments. FIG. 21 illustrates an embodiment where the openings in window 138 are diagonal slits. This would result in stripes of epoxy 144 being applied to the substrate 112 beneath the die 102. The slits may be vertical or horizontal in further embodiments. FIG. 22 illustrates an embodiment where the openings in window 138 are circular holes. This would result in circles of epoxy 144 being applied to the substrate 112 beneath the die 102. Further configurations of window 138 are contemplated.

In embodiments, the semiconductor die 102 may be one or more flash memory chips so that, with controller die 184, the device 190 may be used as a flash memory device. It is understood that the device 190 may include semiconductor die configured to perform other functions in further embodiments of the present system. The device 190 may be used in a plurality of standard memory cards, including without limitation a CompactFlash card, a SmartMedia card, a Memory Stick, a Secure Digital card, a miniSD card, a microSD card, a USB memory card and others.

In summary, in embodiments, the present technology relates to a substrate panel, comprising: a plurality of substrates; and a plurality of discrete areas of die attach epoxy applied without a semiconductor die onto the substrate.

In further embodiments, the present technology relates to a system for forming a substrate panel, comprising: a panel including plurality of substrates, the substrates each including an area for receiving a semiconductor die; and a window clamp, capable of being received over the panel, and including one or more windows through which epoxy is applied to the areas on the substrate for receiving a semiconductor die.

In further embodiments, the present technology relates to a method of fabricating a semiconductor panel, comprising the steps of: (a) defining a plurality of substrates on the panel, each substrate including a conductance pattern and an area for receiving a semiconductor die; and (b) applying a liquid epoxy to the area of each substrate for receiving a semiconductor die.

In still further embodiments, the present technology relates to a method of fabricating a semiconductor device, comprising the steps of: (a) defining a plurality of substrates on the panel, each substrate including a conductance pattern and an area for receiving a semiconductor die; (b) positioning a window clamp over at least a portion of the substrate panel, the window clamp including at least one of a column and a row of windows; (c) spraying a liquid epoxy through the at least one column and row of windows onto the areas of the substrates for receiving a semiconductor die; and (d) mounting semiconductor die on the areas of the substrate that received the liquid epoxy in said step (c).

The foregoing detailed description of the invention has been presented for purposes of illustration and description. It is not intended to be exhaustive or to limit the invention to the precise form disclosed. Many modifications and variations are possible in light of the above teaching. The described embodiments were chosen in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

We claim:

1. A substrate panel, comprising:
a plurality of substrates; and
a plurality of discrete areas of die attach epoxy applied without a semiconductor die onto the substrate.

2. The substrate panel of claim 1, wherein the discrete areas of die attach epoxy are applied in a size and shape matching a size and shape of semiconductor die to be mounted on the substrate panel.

3. The substrate panel of claim 1, wherein the discrete areas of die attach epoxy are applied in a size and shape that are smaller than a size and shape of semiconductor die to be mounted on the substrate panel.

4. A system for forming a substrate panel, comprising:
a panel including plurality of substrates, the substrates each including an area for receiving a semiconductor die; and
a window clamp, capable of being received over the panel, and including one or more windows through which epoxy is applied to the areas on the substrate for receiving a semiconductor die.

5. The system of claim 4, wherein the one or more windows are a column of windows matching the number and positions of substrates in a column on the panel.

6. The system of claim 5, wherein the windows in the column correspond to the size, shape and positions of the areas for receiving semiconductor die in the column of substrates.

7. The system of claim 4, wherein the one or more windows are a row of windows matching the number and positions of substrates in a row on the panel.

8. The system of claim 7, wherein the windows in the row correspond to the size, shape and positions of the areas for receiving semiconductor die in the row of substrates.

9. The system of claim 4, wherein the one or more windows comprise an array of columns and rows of windows matching the number and positions of a number of columns and rows of substrates on the panel.

10. The system of claim 4, further comprising a clean-up follower for removing epoxy applied to the window clamp.

11. The system of claim 10, the clean-up follower including a cloth which contacts the window clamp to absorb epoxy applied to the window clamp.

12. The system of claim 10, further comprising a window cleaning mechanism for removing epoxy applied to sidewalls of the one or more windows of the window clamp.

13. The system of claim 4, further comprising a spray head for applying liquid epoxy through the one or more windows.

14. The system of claim 13, wherein the spray head is mounted to translate along a column or row of windows in the window clamp.

15. A method of fabricating a semiconductor panel, comprising the steps of:
(a) defining a plurality of substrates on the panel, each substrate including a conductance pattern and an area for receiving a semiconductor die; and
(b) applying a liquid epoxy to the area of each substrate for receiving a semiconductor die.

16. The method of claim 15, further comprising the step of masking portions on the substrates outside of the area for receiving the semiconductor die to prevent liquid epoxy from being applied to the portions of the substrate.

17. The method of claim 15, said step (b) comprising the step of using a window clamp having windows through which the epoxy is sprayed.

18. The method of claim 17, further comprising the step (d) of removing epoxy applied to the window clamp.

19. The method of claim 15, further comprising the step (e) of partially curing the epoxy after said step (b) to a B-stage epoxy.

20. The method of claim 15, said step (b) comprising the step of applying the epoxy to an entire column of substrates at the same time.

21. The method of claim 15, said step (b) comprising the step of applying the epoxy to an entire row of substrates at the same time.

22. The method of claim 15, said step (b) comprising the step of applying the epoxy to an array of rows and columns at the same time.

23. A method of fabricating a semiconductor device, comprising the steps of:
(a) defining a plurality of substrates on the panel, each substrate including a conductance pattern and an area for receiving a semiconductor die;
(b) positioning a window clamp over at least a portion of the substrate panel, the window clamp including at least one of a column and a row of windows;
(c) spraying a liquid epoxy through the at least one column and row of windows onto the areas of the substrates for receiving a semiconductor die; and
(d) mounting semiconductor die on the areas of the substrate that received the liquid epoxy in said step (c).

24. The method of claim 23, further comprising the step of the window clamp masking portions on the substrates outside of the area for receiving the semiconductor die to prevent liquid epoxy from being applied to the portions of the substrate.

25. The method of claim 23, further comprising the step (e) of removing epoxy applied to the window clamp.

26. The method of claim 23, further comprising the step (f) of partially curing the epoxy before said step (d) of mounting semiconductor die on the areas of the substrate.

27. The method of claim 26, further comprising the step (g) of further curing the epoxy after said step (d) of mounting semiconductor die on the areas of the substrate.

28. The method of claim 23, said step (c) comprising moving a spray head spraying the epoxy along one of the column or row to spray the epoxy through the windows of the column or row.
